(19) United States
(12) Patent Application Publication
(10) Pub. No.: US 2002/0024093 A1
(43) Pub. Date: Feb. 28, 2002

(54) Semiconductor device with self-aligned contact structure employing dual spacers and method of manufacturing the same

(76) Inventors: Tae-Hyuk Ahn, Yongin-si (KR); Myeong-Cheol Kim, Suwon-si (KR); Sang-Sup Jeong, Suwon-si (KR)

Correspondence Address: JONES VOLENTINE, P.L.L.C., Suite 150, 12200 Sunrise Valley Drive, Reston, VA, 20191, US

(21) Appl. No.: 09/933,674

(22) Filed: Aug. 22, 2001

(30) Foreign Application Priority Data
Aug. 23, 2000 (KR) 2000-48819

(51) Int. Cl. H01L 29/76; H01L 29/94

(52) U.S. Cl. 257/332; 257/387; 438/270; 438/299

(57) ABSTRACT

A semiconductor device having a self-aligned contact and a method of manufacturing the same. The device comprises a semiconductor substrate and two spaced apart conductor structures formed on the substrate. Each of the conductor structures includes a first conductive layer covered with a silicon nitride mask layer. Silicon oxide spacers are formed on the sides of each conductor structure to a height lower than the top surface of the silicon nitride mask layer. Silicon nitride spacers are formed on the sides of each conductor structure and the surface of the silicon oxide spacers. Over the conductor structures and substrate, there is formed an insulating layer of silicon oxide having a self-aligned contact hole exposing the silicon nitride spacers and partially extending over each conductor structure. The self-aligned contact hole is filled up with a second conductive layer self-aligned to the conductor structures. The dual spacers, consisting of the silicon oxide spacer and the silicon nitride spacer, formed on the sides of the conductor structure, decrease the loading capacitance between the first conductive layer and the second conductive layer within the self-aligned contact hole, while still providing sufficient insulation against shorts.

### BACKGROUND OF THE INVENTION

1. Field of the Invention

The present invention relates to a semiconductor device and a method of manufacturing the same, and more particularly, to a semiconductor device having a self-aligned contact structure employing dual spacers of separate materials and a method of manufacturing the same.

2. Description of the Related Art

As the elements of a semiconductor device become more densely integrated, feature sizes of patterns formed on a chip, the width of a wiring layer, and the space between the wiring layers, are becoming smaller and smaller. In particular, an important process in any semiconductor device fabrication process is the formation of contacts connecting isolated device regions formed in a semiconductor substrate with a conductor film. A key consideration in the formation of these contacts is securing sufficient alignment and isolation margins, which has led to increased contact areas. Accordingly, in memory devices such as dynamic random access memory (DRAM), the contact area is a significant factor determining the size of a memory cell.

In highly integrated semiconductor devices employing no more than 0.25 micron technology, it becomes difficult to form small contact holes according to conventional fabrication methods. More particularly, in memory devices using a plurality of conductive layers, the height between the conductive layers is increased due to an insulating interlayer interposed therebetween, so that the formation of a contact between the conductive layers becomes very difficult. Accordingly, in such cases where the controlling design rule is limited and complex patterns such as memory cells are repeated, a method has been developed wherein a contact hole is formed by a self-alignment technique so as to reduce the cell area.

In the conventional self-aligned contact technique, the contact is formed using the step differential of a peripheral structure. Contacts of various sizes can be obtained without using a mask, depending on the peripheral structure height, the insulating material thickness at the point where the contact hole will be formed, and the etching method. In this widely used self-aligned contact process, a contact hole is formed by relying on the etching selectivity of the oxide and nitride layers while employing an anisotropic etching process.

FIG. 1 is a cross-sectional view of a semiconductor device having a self-aligned contact structure formed according to a conventional method. Referring to FIG. 1, line type conductor structures 19 formed on a semiconductor substrate 10 include a first conductive layer 16 and a silicon nitride layer 18 stacked on first conductive layer 16. After forming silicon nitride spacers 20 on the sides of each of the conductor structures 19, an insulating layer 22 made of a silicon oxide is formed over the conductor structures 19 and substrates 10. Then, employing an anisotropic etching process using the selective etch rates of the silicon oxide and silicon nitride layers, the silicon oxide insulating layer 22 is etched away to form a self-aligned contact hole 23 exposing the substrate region between the conductor structures 19.

After depositing a second conductive layer 24, which fills the self-aligned contact hole 23, the second conductive layer 24 is removed by an etch-back method or a chemical mechanical polishing (CMP) method until the upper surface of insulating layer 22 is exposed. As a result, a self-aligned contact structure is formed in the self-aligned contact hole 23.

In this conventional method, the silicon oxide insulating layer 22 is etched on condition that the silicon oxide is etched faster than the silicon nitride of the silicon nitride layer 18 stacked on first conductive layer 16, thereby forming the self-aligned contact hole 23. Since silicon nitride is a nonconductive material, no electrical short is generated between the first conductive layer 16 covered with the silicon nitride layer 18 and the second conductive layer 24 within self-aligned contact hole. However, since the dielectric constant of silicon nitride is 7.5, the capacitance between the first conductive layer 16 and the second conductive layer 24 is increased by a factor of two, as compared to a general contact structure in which the first conductive layer is electrically insulated from the second conductive layer using a silicon oxide layer whose dielectric constant is 3.9.

In the case of a DRAM device, where a capacitor contact hole is formed so as to be self-aligned to a bit-line using the above-described self-aligned contact structure, a bit-line capacitance (C_{BL}) is increased as compared with a general contact structure in which the bit-line and capacitor contact plug (i.e., storage electrode) are insulated from each other by the silicon oxide layer, which results in decreased cell capacitance. For example, if a self-aligned capacitor contact hole is formed in a DRAM device having a design rule of 0.15 um, a loading capacitance between the bit-line and the storage electrode is increased so that the bit-line capacitance (C_{BL}) is increased to 30 fF.

FIG. 2 is a cross-sectional view of a semiconductor device having a self-aligned contact structure according to another conventional method which employs dual spacers. Referring to FIG. 2, line type conductor structures 39 formed on a semiconductor substrate 30 include a first conductive layer 36 covered with a silicon nitride layer 38. On the sides of conductor structures 39, two spacers consisting of a silicon oxide spacer 40 and a silicon nitride spacer 42 are formed. An insulating layer 44 is formed over the conductor structures 39 and the substrate 30, and is patterned to form a self-aligned contact hole 45 exposing a portion of the substrate 30 between the conductor structures 39. The self-aligned contact hole 45 is filled with a second conductive layer 46 to thereby form a self-aligned contact structure.

According to this second conventional method, the spacers 40 made of silicon oxide, having a lower dielectric constant than silicon nitride, are formed on the sides of the conductor structures 39, and then, the spacers 42 made of silicon nitride are further formed to realize the self-aligned contact. However, if a misalignment occurs during a lithography process for the self-aligned contact, a undesirable situation my result in which the etching progresses in the vicinity of the corners of the conductor structures 39, such that the silicon oxide spacer 40 is etched quickly, together with the silicon oxide insulating layer 44, and thus, the surface of the first conductive layer 36 may be exposed. As a result, an electrical short may be generated between the first conductive layer 36 and the second conductive layer 45 within self-aligned contact hole 45.

Another conventional method in which a self-aligned contact structure is realized using dual spacers consisting of a silicon oxide spacer and a silicon nitride spacer is disclosed in U.S. Pat. No. 5,899,722. FIG. 3 is a cross-sectional view of a semiconductor device disclosed in the above U.S. patent.

Referring to FIG. 3, line type conductor structures 59 formed on a semiconductor substrate 50 include a first conductive layer 56 covered with a silicon nitride layer 58. A silicon nitride spacer 60 and a silicon oxide spacer 62 are successively formed on the sides of the conductor structures 59. A silicon oxide insulating layer 64 is formed over the conductor structures 59 and the substrate 50. By employing an anisotropic etching process using the selective etch rates of the silicon oxide and silicon nitride layers, the insulating layer 64 is etched away to form a self-aligned contact hole 65 exposing a portion of the substrate 50 between the conductor structures 59.

During this anisotropic etching process, the silicon oxide spacers 62 within the self-aligned contact hole 65 are etched away along with the silicon oxide insulating layer 64. Then, the self-aligned contact hole 65 is filled with a second conductive layer 66 to thereby form a self-aligned contact structure.

According to the method disclosed in U.S. Pat. No. 5,899,722, although a misalignment may occur during a lithography process for forming the self-aligned contact, such that the etching progresses in the vicinity of the corners of conductor structure 59, no electrical short is generated between the first conductive layer 56 and the second conductive layer 66, because the upper surface and the sides of the first conductive layer 56 are covered with the non-conducting silicon nitride layer 58 and silicon nitride spacers 60. However, since the silicon oxide spacer 62 within the self-aligned contact hole 65 is removed during the etching process, only the silicon nitride spacer 60 having a higher dielectric constant than the silicon oxide exists between the first conductive layer 56 and the second conductive layer 66, which is similar to the conventional method shown in FIG. 1. Accordingly, the loading capacitance between the first conductive layer 56 and the second conductive layer 66 within the self-aligned contact hole 65 is not decreased, and is similar to that described with regard to FIG. 1.

U.S. Pat. Nos. 5,731,236, 5,766,992, and 5,817,562, also generally disclose methods in which a silicon nitride spacer is formed after a silicon oxide spacer is formed on the sides of a conductor structure. According to these methods, since the silicon oxide spacer is formed by a thermal oxidation process, the silicon oxide spacer is very thin (e.g. a thickness less than about 100 Å), which does not result in any reduction of loading capacitance. However, when the silicon oxide spacer is etched rather fast during the etching process for the self-aligned contact, an electrical short is generated between the conductor layer and the conductive structure within the self-aligned contact hole. Further, in cases where the conductor is comprised of a metal that can be easily oxidized, these methods cannot be applied.

### SUMMARY OF THE INVENTION

Therefore, it is a first object of the present invention to provide a semiconductor device for decreasing the loading capacitance between a first conductive layer and a second conductive layer within a self-aligned contact hole.

It is a second object of the present invention to provide a DRAM device in which a capacitor contact hole is formed by a self-aligned contact process to a bit-line, thereby decreasing the loading capacitance between the bit-line and a conductive layer within the capacitor contact hole.

It is a third object of the present invention to provide a method of manufacturing a semiconductor device for decreasing the loading capacitance between a first conductive layer and a second conductive layer within a self-aligned contact hole.

It is a fourth object of the present invention to provide a method of manufacturing a DRAM device for decreasing the loading capacitance between a bit-line and a second conductive layer within a capacitor contact hole that is self-aligned to the bit-line.

In accordance with a first aspect of the present invention, there is provided a semiconductor device comprising a semiconductor substrate, and two spaced apart conductor structures formed on the semiconductor substrate, where each of the conductor structures has a first conductive layer and a silicon nitride mask layer stacked on the first conductive layer. Silicon oxide spacers are formed on sides of each of the conductor structures, wherein a top surface of the silicon oxide spacers is formed to a height lower than that of a top surface of silicon nitride mask layer, thereby partially exposing upper side portions of the conductor structures. Then, silicon nitride spacers are formed on the exposed upper side portions of each of the conductor structures and the surface of the silicon oxide spacers. An insulating layer covers the conductor structures and the semiconductor substrate, with the insulating layer having a self-aligned contact hole exposing the silicon nitride spacers between the spaced apart conductor structures. A second conductive layer fills the self-aligned contact hole and is self-aligned to the conductor structures.

In the second aspect of the invention, there is provided a dynamic random access memory device comprising a first insulating interlayer formed on a semiconductor substrate in which transistors consisting of a gate, a capacitor contact region and a bit-line contact region are formed. The first insulating interlayer has a bit-line contact hole exposing the bit-line contact region. Two spaced bit-line structures are formed on the first insulating interlayer. The capacitor contact region is positioned below and aligned between the bit-line structures, and each of the bit-line structures includes a bit-line making contact with the bit-line contact region via the bit-line contact hole, and a silicon nitride mask layer stacked on the bit-line. Silicon oxide spacers are formed on sides of each of the bit-line structures, wherein a top surface of the oxide spacers is formed to a height lower than that of a top surface of silicon nitride mask layer, thereby partially exposing upper side portions of the bit-line structures. Silicon nitride spacers are formed on the exposed upper side portions of each of the bit-line structures and the surface of the silicon oxide spacers. A second insulating interlayer, formed on the bit-line structures and the first insulating interlayer, contains a self-aligned contact hole exposing the silicon nitride spacers in the capacitor contact region. A capacitor conductive layer fills up the self-aligned contact hole and is self-aligned to the bit-line structures.

According to the present invention, dual spacers (i.e., a silicon oxide spacer and a silicon nitride spacer) are formed on the sides of the conductor structures comprising the first conductive layer covered with the silicon nitride mask layer. The sides of the first conductive layer are covered with the silicon oxide spacers having a low dielectric constant, thereby decreasing the loading capacitance between the first conductive layer and the second conductive layer within the self-aligned contact hole.

Further, since the top surface of the silicon oxide spacers are formed to a height lower than the top surface of the silicon nitride mask layer, only silicon nitride spacers exist at the corners of the conductor structure. Accordingly, although a misalignment may be generated during a lithography process for the self-aligned contact, no electrical short is generated between the first conductive layer and the second conductive layer within the self-aligned contact hole.

### BRIEF DESCRIPTION OF THE DRAWINGS

The above features and other advantages of the present invention will become more apparent with reference to the illustrative embodiments taken in connection with the attached drawings in which:

FIG. 1 is a cross-sectional view of a semiconductor device having a self-aligned contact structure according to one conventional method;

FIG. 2 is a cross-sectional view of a semiconductor device having a self-aligned contact structure according to another conventional method;

FIG. 3 is a cross-sectional view of a semiconductor device having a self-aligned contact structure according to still another conventional method;

FIG. 4 is a cross-sectional view of a semiconductor device having a self-aligned contact structure according to one embodiment of the present invention;

FIG. 5 is a plan view of a DRAM device according to a preferred embodiment of the present invention;

FIG. 6 is a cross-sectional view of a DRAM device having a self-aligned contact hole according to a first embodiment of the present invention, taken along line 6-6′ in FIG. 5;

FIGS. 7A to 7H are cross-sectional views illustrating a method of manufacturing the DRAM device shown in FIG. 6; and

FIG. 8 is a cross-sectional view of a DRAM device having a self-aligned contact hole according to a second embodiment of the present invention, taken along line 8-8′ in FIG. 5.

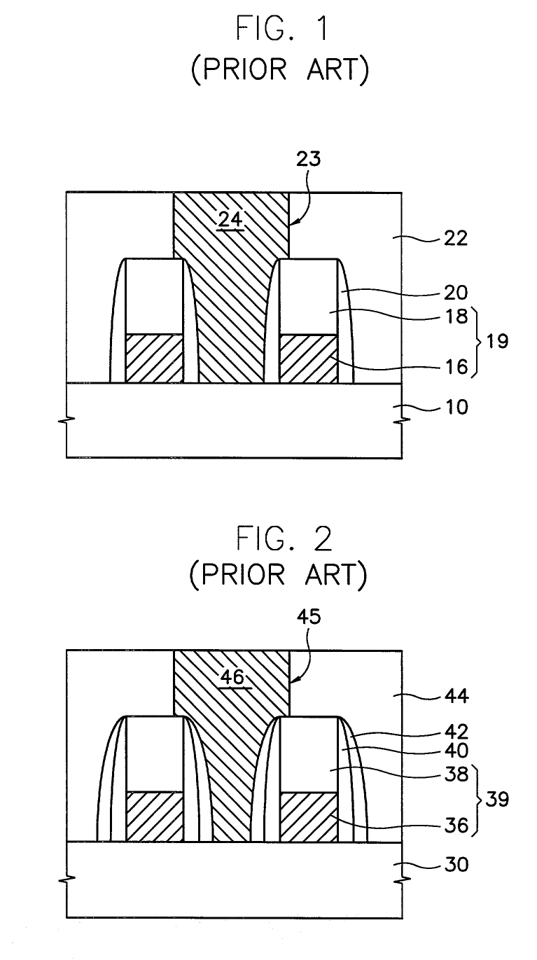

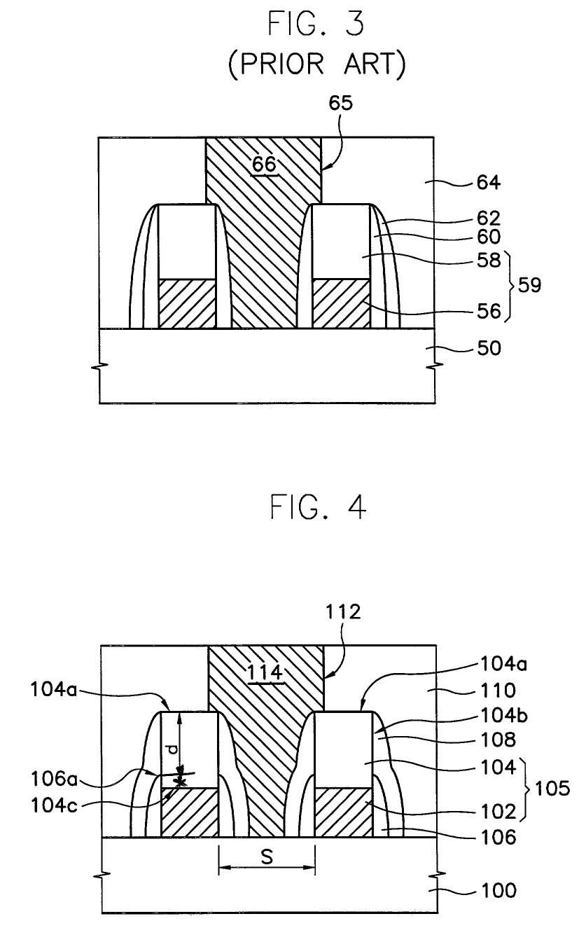

### DESCRIPTION OF PREFERRED EMBODIMENTS

The present invention now will be described more fully with reference to the accompanying drawings, in which preferred embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thickness of layers and regions are exaggerated for clarity. It will also be understood that when a layer is referred to as being “on” another layer or substrate, it can be directly on the other layer or substrate, or intervening layers may also be present.

FIG. 4 is a cross-sectional view of a semiconductor device having a self-aligned contact structure according to one embodiment of the present invention. Referring to FIG. 4, two conductor structures 105, each including a first conductive layer 102 and a silicon nitride mask layer 104 stacked on the first conductive layer 102, are formed on a semiconductor substrate 100. The line type conductor structures 105 are formed with a predetermined space (S) therebetween. Preferably, the first conductive layer 102 is comprised of a metal such as tungsten (W), titanium (Ti) or titanium nitride (TiN). Alternatively, the first conductive layer 102 may be comprised of doped polysilicon.

Dual spacers, consisting of a silicon oxide spacer 106 and a silicon nitride spacer 108, are formed on the sides of each of the conductor structures 105. The silicon oxide spacer 106 is formed to a height lower than the top surface 104a of the silicon nitride mask layer 104, thereby partially exposing the upper portions of the sides 104b of each of the conductor structures 105. The silicon nitride spacer 108 is an outer spacer and is formed continuously on the exposed sides 104b of each of the conductor structures 105 and on the surfaces of the silicon oxide spacers 106.

Preferably, the silicon oxide spacer 106 is comprised of a chemical vapor deposited silicon oxide, and is formed so that the distance (d) between the top surface 104a of the silicon nitride mask layer 104 to the top surface 106a of the silicon oxide spacer 106 is more than about 300 Å. In an alternate embodiment, the top surface 106a of the silicon oxide spacer 106 may be formed lower than the bottom surface 104c of the silicon nitride mask layer 104.

Over the conductor structures 105 and the semiconductor substrate 100, a silicon oxide insulating layer 110 is formed, which is thereafter patterned to form a self-aligned contact hole 112 exposing the silicon nitride spacers 108 in the space (S) between the conductor structures 105. The silicon oxide insulating layer 110 also partially extends over the top of each of the conductor structures 105.

The self-aligned contact hole 112 is filled with a second conductive layer 114. The second conductive layer 114 is self-aligned to the conductor structures 105, thereby forming a self-aligned contact structure. The second conductive layer 114 may be formed to a contact plug type as shown in FIG. 4, or may be formed to a predetermined pattern by a conventional lithography process.

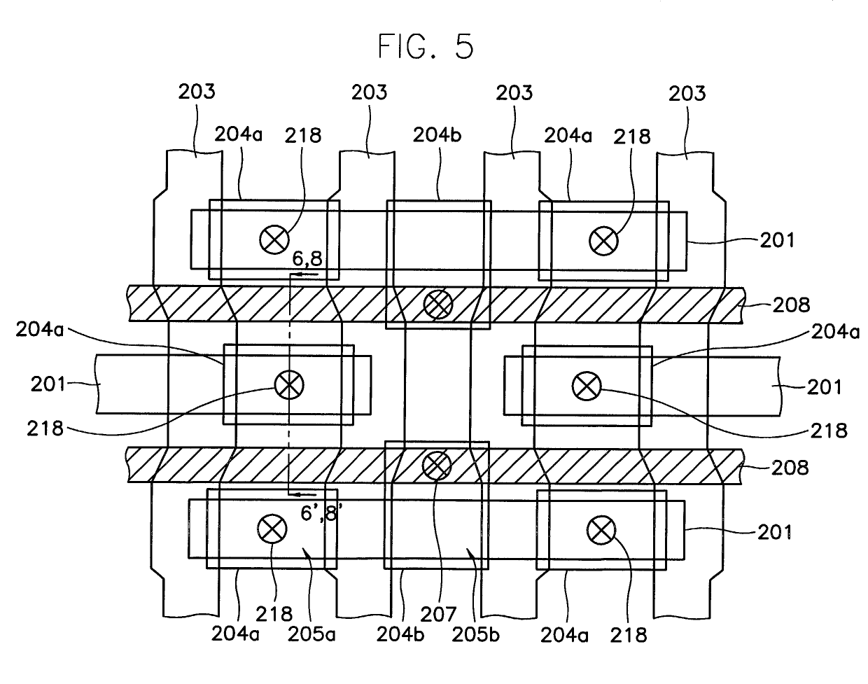

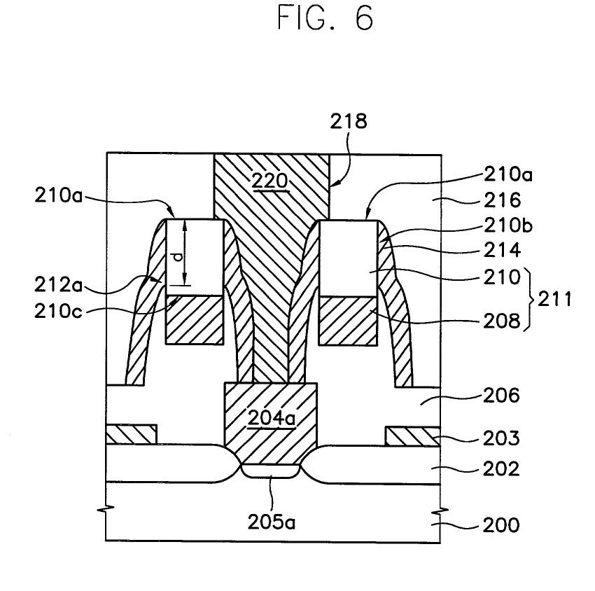

FIG. 5 is a plan view of a DRAM device according to a preferred embodiment of the present invention and shows a memory cell region. FIG. 6 is a cross-sectional view of a DRAM device having a self-aligned contact hole according to a first embodiment of the present invention, taken along line 6-6′ in FIG. 5.

Referring to FIGS. 5 and 6, on a semiconductor substrate 200 divided into an active region 201 and an isolation region by a field oxide layer 202, there are formed transistors consisting of a gate 203 for a word-line, a capacitor contact region (e.g., source region) 205a, and a bit-line contact region (e.g., drain region) 205b. Over the source/drain regions 205a and 205b of the transistor, pad electrodes 204a and 204b may be formed to decrease the aspect ratios of contact holes being formed thereon.

Over the transistors and the semiconductor substrate 200, there is formed a first insulating interlayer 206 having a bit-line contact hole 207 exposing the drain region 205b, or the pad electrode 204b making contact with the drain region 205b.

On the first insulating interlayer 206, there are formed two bit-line structures 211, including a bit-line 208 making contact with the drain region 205b via the bit-line contact hole 207, and a silicon nitride mask layer 210 stacked on the bit-line 208. Each of the bit-line structures 211 is patterned to a line type. Underlying, and positioned between the bit-line structures 211, is the capacitor contact region (e.g., the source region 205a or the pad electrode 204a making contact with the source region 205a). In other words, the capacitor contact region is positioned below and aligned between the bit-line structures.

Dual spacers are formed on the sides of each of the bit-line structures 211, and include a silicon oxide spacer 212 and a silicon nitride spacer 214. The silicon oxide spacer 212 is formed to a height lower than the top surface 210a of the silicon nitride mask layer 210, thereby partially exposing the upper portions of the sides 210b of each of the bit-line structures 211. Preferably, the silicon oxide spacer 212 is comprised of a CVD-silicon oxide and formed so that the distance (d) between the top surface 210a of the silicon nitride mask layer 210 to the top surface 212a of the silicon oxide spacer 212 is more than about 300 Å. In an alternate embodiment, the top surface 212a of the silicon oxide spacer 212 may be formed lower than the bottom surface 210c of the silicon nitride mask layer 210.

The silicon nitride spacer 214 is an outer spacer and is formed continuously on the sides 210b of each of the bit-line structures 211 and on the surface of the silicon oxide spacers 212.

A second insulating interlayer 216 is formed on the bit-line structures 211 and the first insulating interlayer 206. Through the second insulating interlayer 216, there is formed a self-aligned contact hole 218 exposing the silicon nitride spacers 214 in the capacitor contact region (e.g., the source region 205a or the pad electrode 204a making contact with the source region 205a), and partially extending over the top surface of each of the bit-line structures 211.

The self-aligned contact hole 218 is filled up with a capacitor conductive layer 220. The capacitor conductive layer 220 is self-aligned to the bit-line structures 211 to thereby form a self-aligned contact structure. The capacitor conductive layer 220 may be formed to a contact plug type as shown in FIG. 6, or may be formed to a storage electrode pattern by a conventional lithography process.

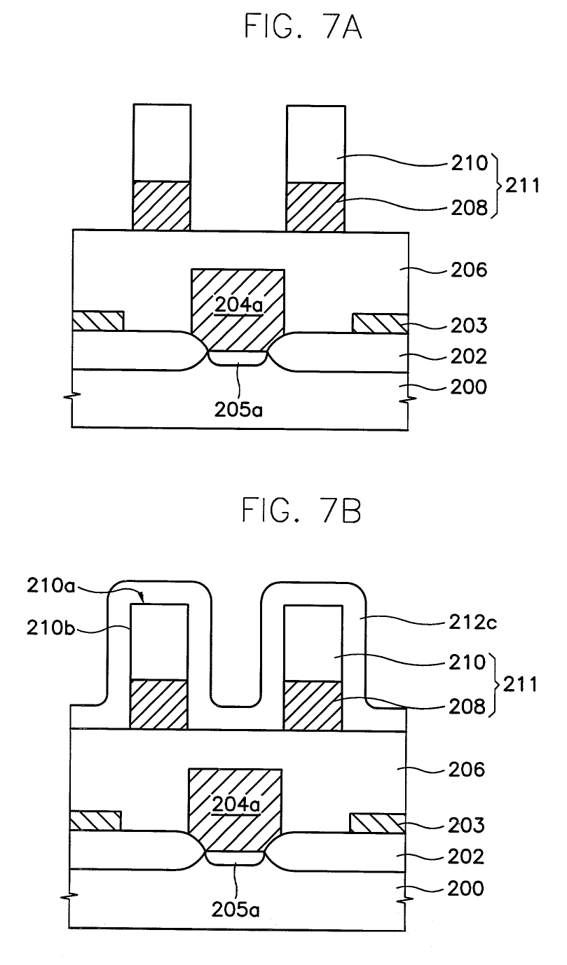

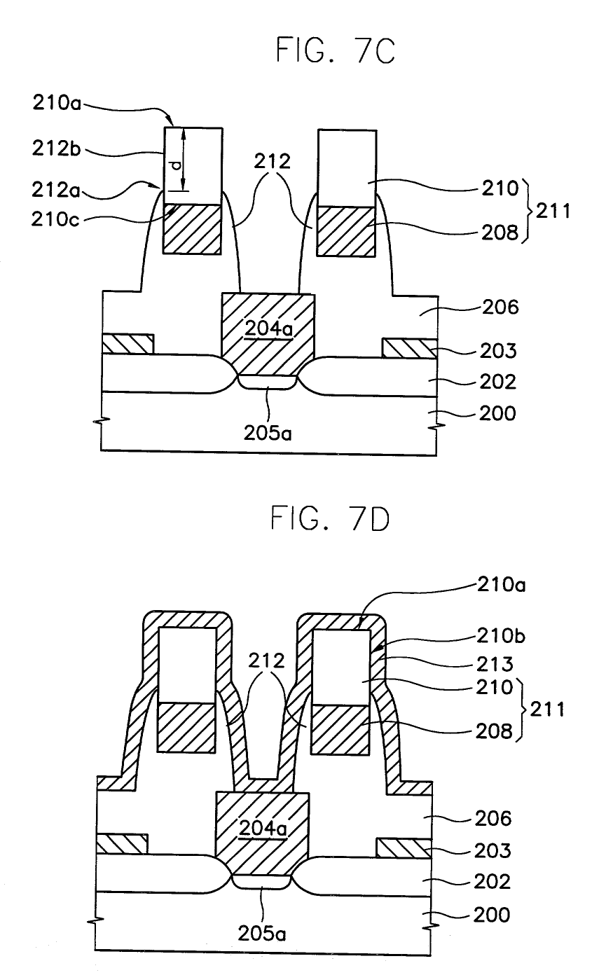

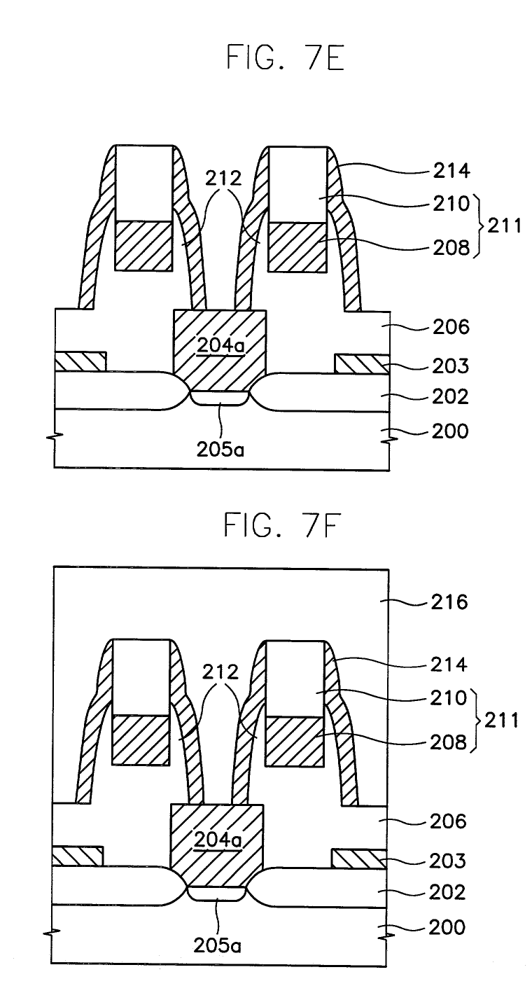

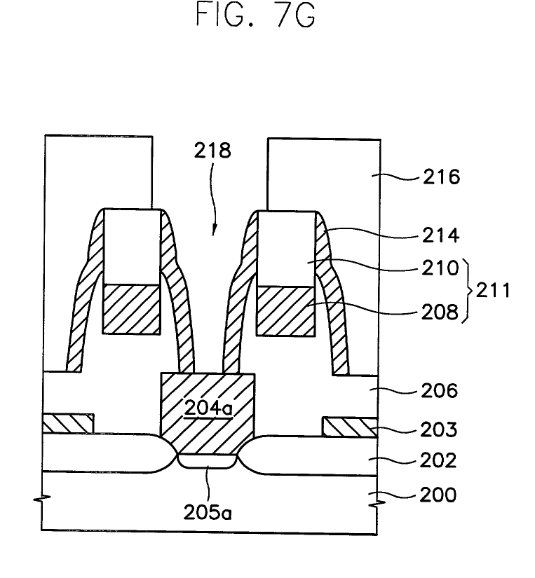

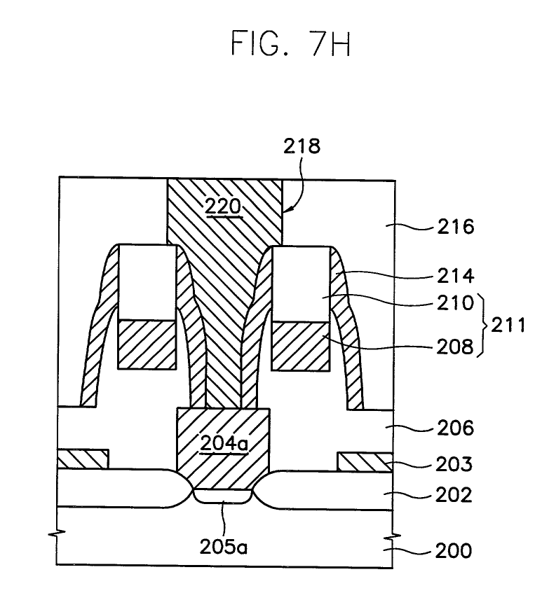

FIGS. 7A to 7H are cross-sectional views illustrating a method of manufacturing the DRAM device shown in FIG. 6. FIG. 7A illustrates the step of forming the bit-line structures 211. According to a conventional isolation process, e.g., an improved LOCOS (Local Oxidation of Silicon) process, a field oxide layer 202 is formed on a semiconductor substrate 200. Accordingly, the semiconductor substrate 200 is divided into an active region (201 in FIG. 5) and an isolation region.

Then, the transistors are formed on the active region 201 of the semiconductor substrate 200. Specifically, after growing a thin gate oxide layer (not shown) on the surface of the active region 201 using a thermal oxidation process, a gate 203 is formed thereon for use as a word-line. Preferably, the gate 203 has a polycide structure comprising a polysilicon layer (which is highly doped using a conventional doping process such as diffusion, ion implantation or in-situ doping) and a tungsten silicide layer stacked on the polysilicon layer. Further, the gate 203 is covered with a silicon oxide layer or a silicon nitride layer (not shown). On the sides of the gate 203, there are formed spacers (not shown) made of silicon oxide or silicon nitride. Then, using the gate 203 as a mask, impurity ions are implanted to form source/drain regions 205a and 205b in the surface of the active region 201. One of these doping regions is a capacitor contact region that will be connected with a storage electrode of a capacitor, and another is a bit-line contact region that will be connected with a bit-line. In the embodiment, the source region 205abecomes the capacitor contact region and the drain region 205b becomes the bit-line contact region.

Then, an insulating layer (not shown) is deposited over the transistors and field oxide region 202 and partially etched through a lithography process, thereby partially exposing the source/drain regions 205a and 205b. A polysilicon layer is deposited on the entire surface of the resultant structure and patterned to form the pad electrodes 204a and 204b making contact with the source/drain regions 205a and 205b, respectively. Alternatively, the pad electrodes 204a and 204b may be formed by a self-aligned contact process.

Then, a borophosphosilicate glass (BPSG) or an undoped silicate glass (USG) is deposited over the pad electrodes 204a and 204b and the semiconductor substrate 200, thereby forming a first insulating interlayer 206. The first insulating interlayer 206 is planarized by a reflow method, an etch-back method or a chemical mechanical polishing (CMP) method. By using a lithography process, the first insulating interlayer 206 is partially etched away to form a bit-line contact hole (207 in FIG. 5) exposing the pad electrode 204b making contact with the drain region 205b.

Then, after depositing a metal such as tungsten (W), titanium (Ti) or titanium nitride (TiN) to a thickness of about 1000˜1200 Å so as to fill up the bit-line contact hole 207, a silicon nitride layer is deposited to a thickness of about 1800˜2000 Å thereon. The silicon nitride layer and the deposited metal are patterned through a lithography process, thereby forming the line type bit-line structures 211 including a bit-line 208 and a silicon nitride mask layer 210. Alternatively, the bit-line 208 may be comprised of a doped polysilicon instead of the above-described metal materials.

Referring to FIG. 7B, a silicon oxide layer 212c is deposited by a chemical vapor deposition (CVD) method over bit-line structures 211 and first insulating interlayer 206.

Referring to FIG. 7C, using the high selective etch ratio of the silicon oxide layer 212c with respect to the silicon nitride layer 210, the silicon oxide layer 212c is anisotropically etched away to form silicon oxide spacers 212 on the sides of each of the bit-line structures 211. The silicon oxide spacer 212 is formed to a height lower than the top surface 210a of the silicon nitride layer 210, thereby partially exposing the upper portions of the sides 210b of each of the bit-line structures 211. Preferably, the silicon oxide spacer 212 is comprised of a CVD-silicon oxide and formed so that the distance (d) between the top surface 210a of the silicon nitride mask layer 210 to the top surface 212a of the silicon oxide spacer 212 is more than about 300 Å, preferably 1000 Å. The height of the silicon oxide spacer 212 is preferably about 200˜400 Å. Alternatively, the top surface 212a of the silicon oxide spacer 212 may be formed lower than the bottom surface 210c of the silicon nitride mask layer 210. Preferably, the etch selectivity of the silicon oxide to the silicon nitride layers is more than 5:1. The etching process is carried out using an etchant gas which includes a gas in which the ratio (atomic ratio) of carbon (C) with respect to fluorine (F) is 1:2 or greater. Examples of the etchant gas comprise a mixture gas including any one among C₄F₈, C₅F₈, and C₄F₆, oxygen (O₂) gas and argon (Ar) gas.

Referring to FIG. 7D, using a low pressure chemical vapor deposition (LPCVD) method, a silicon nitride layer 213 is deposited continuously on the first insulating interlayer 206, the upper surface 210a and the sides 210b of the bit-line structures 211, and the surfaces of the silicon oxide spacers 212.

Referring to FIG. 7E, the silicon nitride layer 213 is anisotropically etched away to form the silicon nitride spacers 214 on the previously exposed sides 210b of each of the bit-line structures 211 and the surfaces of the silicon oxide spacers 212. The silicon nitride spacers 214 serve as a shoulder for protecting the bit-line structures 211 during a subsequent etching process for forming a self-aligned contact.

Referring to FIG. 7F, a silicon oxide layer is deposited to a thickness of about 8000˜15000 Å on the resultant structure, thereby forming a second insulating interlayer 216.

Referring to FIG. 7G, after coating a photoresist layer on second insulating interlayer 216, the photoresist layer is exposed and developed using a mask for the self-aligned contact, thereby forming a photoresist pattern (not shown) exposing a self-aligned contact region. By using the photoresist pattern as a mask, the second insulating interlayer 216 is anisotropically etched using the high selective etch ratio of the silicon oxide with respect to the silicon nitride layers, thereby forming a self-aligned contact hole 218 exposing the source region 205a, or the pad electrode 204a making contact with source region 205a, and the silicon nitride spacer 214 thereon.

Referring to FIG. 7H, the photoresist pattern is removed by ashing and strip processes. Then, a capacitor conductive layer 220, e.g., a doped polysilicon, is deposited by a CVD method so as to fill up the self-aligned contact hole 218. The capacitor conductive layer 220 is removed by an etch-back or a CMP process until the upper surface of the second insulating interlayer 216 is exposed, thereby leaving only plug type capacitor conductive layer 220 inside the self-aligned contact hole 218. Alternatively, the capacitor conductive layer 220 may be patterned to a storage electrode pattern by a conventional lithography process.

Then, through general processes of forming a capacitor, there is formed a capacitor consisting of a storage electrode which makes contact with the source region 205a via the self-aligned contact hole 218, a dielectric layer and a plate electrode.

According to the first embodiment of the present invention, the sides of the bit-line 208 are covered with the silicon oxide spacer 212 whose dielectric constant is lower than the silicon nitride, thereby decreasing the loading capacitance (i.e., bit-line capacitance) between the bit-line 208 and the capacitor conductive layer 220 in the self-aligned contact hole 218.

Further, since the top surface 212a of the silicon nitride spacer 212 is lower than the top surface 210a of the silicon nitride mask layer 210, only the silicon nitride spacer 214 exists at the corners of the bit-line structure 211. Accordingly, even if a misalignment occurs during a lithography process for the self-aligned contact, the shoulder margin is secured by the silicon nitride spacer 214 and thus, no electrical short is generated between the bit-line 208 and the contact plug 220.

In order to enhance the reduction effect of the loading capacitance, it is preferred that the top surface 212a of the silicon oxide spacer 212 is higher than the bottom surface 210c of the silicon nitride mask layer 210.

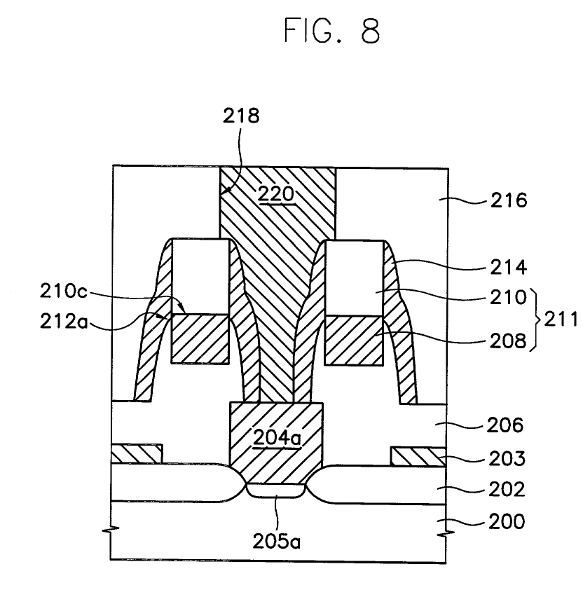

FIG. 8 is a cross-sectional view of a DRAM device having a self-aligned contact hole according to a second embodiment of the present invention, taken along line 8-8′ in FIG. 5.

The DRAM device according to the second embodiment is the same as the above-described first embodiment, except that the top surface 212a of the silicon oxide spacer 212 is lower than the bottom surface 210c of the silicon nitride mask layer 210 to thereby enhance the shoulder margin of the self-aligned contact process.

According to the present invention as described above, on the sides of the conductor structure comprising the first conductive layer covered with the silicon nitride mask layer, dual spacers consisting of the silicon oxide spacer and the silicon nitride spacer are formed. The sides of the first conductive layer are covered with the silicon oxide spacer whose dielectric constant is low, thereby decreasing the loading capacitance between the first conductive layer and the second conductive layer within the self-aligned contact hole.

Further, since the silicon oxide spacer is formed to a height lower than the top of the silicon nitride mask layer, only the silicon nitride spacer exists at the corners of the conductor structure. Accordingly, although a misalignment may occur during a lithography process for the self-aligned contact, no electrical short is generated between the first conductive layer and the second conductive layer within the self-aligned contact hole.

While the present invention has been particularly shown and described with reference to illustrative embodiments thereof, it will be understood by those skilled in the art that various changes in form and details may be effected without departing from the spirit and scope of the invention as defined by the appended claims.

What is claimed is:

1. A semiconductor device comprising:
a semiconductor substrate;
two spaced apart conductor structures formed on said semiconductor substrate, each of said conductor structures having a first conductive layer and a silicon nitride mask layer stacked on said first conductive layer;
silicon oxide spacers formed on sides of each of said conductor structures, wherein a top surface of the silicon oxide spacers is formed to a height lower than that of a top surface of silicon nitride mask layer, thereby partially exposing upper side portions of the conductor structures;
silicon nitride spacers formed on the exposed upper side portions of each of said conductor structures and the surface of said silicon oxide spacers;
an insulating layer formed on said conductor structures and said semiconductor substrate, said insulating layer having a self-aligned contact hole exposing said silicon nitride spacers between said spaced apart conductor structures; and
a second conductive layer filling up said self-aligned contact hole and being self-aligned to said conductor structures.

2. The device as claimed in claim 1, wherein said silicon oxide spacers are formed such that a distance between the top surface of said silicon nitride mask layer and the top surface of said silicon oxide spacers is at least about 300 Å.

3. The device as claimed in claim 1, wherein the top surface of said silicon oxide spacers are formed to a height lower than a bottom surface of said silicon nitride mask layer.

4. The device as claimed in claim 1, wherein said silicon oxide spacers are comprised of a chemical vapor deposited silicon oxide.

5. The device as claimed in claim 1, wherein said first conductive layer is comprised of a metal.

6. A dynamic random access memory device comprising:
a first insulating interlayer formed on a semiconductor substrate in which transistors consisting of a gate, a capacitor contact region and a bit-line contact region are formed, said first insulating interlayer having a bit-line contact hole exposing said bit-line contact region;
two spaced bit-line structures, formed on said first insulating interlayer, having said capacitor contact region positioned below and aligned between said bit-line structures, each of said bit-line structures including a bit-line making contact with said bit-line contact region via said bit-line contact hole, and a silicon nitride mask layer stacked on said bit-line;
silicon oxide spacers formed on sides of each of said bit-line structures, wherein a top surface of the oxide spacers is formed to a height lower than that of a top surface of silicon nitride mask layer, thereby partially exposing upper side portions of the bit-line structures;
silicon nitride spacers formed on the exposed upper side portions of each of said bit-line structures and the surface of said silicon oxide spacers;
a second insulating interlayer formed on said bit-line structures and said first insulating interlayer, said second insulating interlayer having a self-aligned contact hole exposing said silicon nitride spacers in said capacitor contact region; and
a capacitor conductive layer filling up said self-aligned contact hole and being self-aligned to said bit-line structures.

7. The device as claimed in claim 6, wherein said silicon oxide spacers are formed such that a distance between the top surface of said silicon nitride mask layer and the top surface of said silicon oxide spacers is at least about 300 Å.

8. The device as claimed in claim 6, wherein the top surface of said silicon oxide spacers are formed to a height lower than a bottom surface of said silicon nitride mask layer.

9. The device as claimed in claim 6, wherein said silicon oxide spacers are comprised of a CVD-silicon oxide.

10. The device as claimed in claim 6, wherein said bit-line is comprised of a metal.

11. A method of manufacturing a semiconductor device comprising:
forming two spaced apart conductor structures on a semiconductor substrate, each of said conductor structures including a first conductive layer and a silicon nitride mask layer stacked on said first conductive layer;
forming silicon oxide spacers on sides of each of said conductor structures, wherein a top surface of the oxide spacers is formed to a height lower than that of a top surface of silicon nitride mask layer, thereby partially exposing upper side portions of the conductor structures;
forming silicon nitride spacers on the exposed upper side portions of each of said conductor structures and the surface of said silicon oxide spacers;
forming an insulating layer of silicon oxide on said conductor structures and said substrate;
partially etching said insulating layer to form a self-aligned contact hole exposing said silicon nitride spacers between said spaced apart conductors; and
filling said self-aligned contact hole with a second conductive layer to form a self-aligned contact structure.

12. The method as claimed in claim 11, wherein the step of forming said silicon oxide spacers comprises:
depositing a silicon oxide layer on said conductor structures and said substrate by a chemical vapor deposition method; and
anisotropically etching said silicon oxide layer, wherein an etch selectivity of the silicon oxide to the silicon nitride layers is greater than about 5:1, such that a top surface of the oxide spacers is formed to a height lower than that of a top surface of silicon nitride mask layer.

13. The method as claimed in claim 12, further comprising anisotropically etching said silicon oxide layer using an etchant gas including a gas having a ratio of carbon (C) to fluorine (F) of at least 1:2.

14. The method as claimed in claim 13, wherein said gas is at least one selected from the group consisting of C₄F₈, C₅F₈ and C₄F₆.

15. The method as claimed in claim 12, further comprising anisotropically etching said silicon oxide layer until a distance between the top surface of said silicon nitride mask layer and the top surface of said silicon oxide spacers is at least about 300 Å.

16. A method of manufacturing a dynamic random access memory device comprising:
forming a first insulating interlayer on a semiconductor substrate in which transistors consisting of a gate, a capacitor contact region and a bit-line contact region are formed;
partially etching said first insulating interlayer to form a bit-line contact hole exposing said bit-line contact region;
forming two spaced bit-line structures on said first insulating interlayer with said capacitor contact region positioned below and aligned between said bit-line structures, each of said bit-line structures including a bit-line being in contact with said bit-line contact region via said bit-line contact hole and a silicon nitride mask layer stacked on said bit-line;
forming silicon oxide spacers on the sides of each bit-line structure, wherein a top surface of the oxide spacers is formed to a height lower than that of a top surface of silicon nitride mask layer, thereby partially exposing upper side portions of the bit-line structures;
forming silicon nitride spacers on the exposed upper side portions of each of said bit-line structures and the surface of said silicon oxide spacers;
forming a second insulating interlayer on said bit-line structures and said first insulating interlayer;
partially etching said second insulating interlayer to form a self-aligned contact hole exposing said silicon nitride spacers over said capacitor contact region; and
filling said self-aligned contact hole with a capacitor conductive layer to form a self-aligned contact structure.

17. The method as claimed in claim 16, wherein the step of forming said silicon oxide spacers comprises:
depositing a silicon oxide layer on said bit-line structures and said semiconductor substrate by a chemical vapor deposition method; and
anisotropically etching said silicon oxide layer, wherein an etch selectivity of the silicon oxide to the silicon nitride layers is greater than about 5:1, such that a top surface of the oxide spacers is formed to a height lower than that of a top surface of silicon nitride mask layer.

18. The method as claimed in claim 17, further comprising anisotropically etching said silicon oxide layer using an etchant gas including a gas having a ratio of carbon (C) to fluorine (F) of at least 1:2.

19. The method as claimed in claim 18, wherein said gas is at least one selected from the group consisting of C₄F₈, C₅F₈ and C₄F₆.

20. The method as claimed in claim 18, further comprising anisotropically etching said silicon oxide layer until a distance between the top surface of said silicon nitride mask layer and the top surface of said silicon oxide spacers is at least about 300 Å.
